(19) United States
(12) Patent Application Publication
(10) Pub. No.: US 2009/0152097 A1
(43) Pub. Date: Jun. 18, 2009

(54) PLASMA GENERATING DEVICE AND PLASMA GENERATING METHOD

(76) Inventors: Marko Eichler, Braunschweig (DE); Michael Thomas, Lehrk (DE); Eugen Schlittenhardt, Wolfsburg (DE)

Correspondence Address: MILLEN, WHITE, ZELANO & BRANIGAN, P.C., 2200 CLARENDON BLVD., SUITE 1400, ARLINGTON, VA, 22201, US

(21) Appl. No.: 12/063,328

(22) PCT Filed: Aug. 9, 2006
(86) PCT No.: PCT/EP06/07889

§ 371 Date: Dec. 30, 2008

(30) Foreign Application Priority Data
Aug. 11, 2005 (DE) 10 2005 038 079.4

(51) Int. Cl. H05H 1/24; C23C 16/00; H05H 1/34

(52) U.S. Cl. 204/164; 118/723 R; 422/186.04; 422/186.05

(57) ABSTRACT

The present invention relates to a plasma generating device having a first and a second electrode (3, 4) which are at a spacing from each other for generating a plasma (13) between the two electrodes (3, 4), a dielectric (8) which is disposed between the two electrodes (3, 4), a gas inlet (10) in the space between the two electrodes (3, 4) for supply of a plasma generating gas (12), one of the two electrodes (3, 4) having at least one opening (5) as gas outlet from the space between the two electrodes (3, 4), through which the plasma (13), which can be generated between the two electrodes (3, 4), can be expelled parallel to the direction of the electrical field which can be produced by the two electrodes (3, 4) between the two electrodes (3, 4), a grating, net and/or fabric (1) being disposed across the cross-section of the at least one opening (5).

The present invention relates to a plasma generating device and also a plasma generating method for producing a plasma jet which is suitable in particular for the treatment of sheet goods and also of planar and three-dimensional substrates.

Modification of surfaces by means of atmospheric pressure plasma methods is gaining ever greater commercial significance. The methods increasingly allow replacement of environmentally problematic wet chemical processes and cost-intensive low pressure plasma methods which are frequently complex and only capable of inline operation in a restricted manner. Both solids, gases and liquids can be treated with atmospheric pressure plasma methods. They have been established for a fairly long time in particular in ozone generation and polymer surface treatment.

In the treatment of sheet goods, barrier discharge above all is used extensively. In this type of discharge there are located between two conductive electrodes at least one insulator which prevents direct ignition of a short circuit arc between the electrodes when applying a voltage. When applying a medium frequency alternating voltage of typically a few kV at a frequency in the kHz range, microdischarges are formed between the electrodes and can be used for cleaning, activating and coating surfaces.

For treatment, the substrate is guided through between the electrodes. Since the spacing between the electrodes is limited because of the filamentation of the discharge which increases with the spacing, not every thickness of substrate can be treated. Furthermore, the discharges form not only in the gas chamber above the surface of the substrate but also in part between the electrode on which the substrate is situated and the substrate. This effect which is known as rear-side treatment is often undesired and frequently cannot be avoided even with complex measures.

With metallic substrates, the substrate itself generally forms the electrode. Since the formation of the discharges depends directly upon the formation of the electrical field, with uneven substrates in part extremely non-homogeneous discharges result.

In the last few years, atmospheric pressure plasma methods have gained increasingly in importance for the treatment of selected surface regions. DE 195 32 412 describes a cylindrical nozzle in which a direct discharge is ignited and expelled. The disadvantage of the jets resides in particular in the punctiform formation of the plasma beam. This makes uniform treatment of large surfaces difficult.

The emerging plasma has a low temperature when using noble gases. Hence large beam diameters can be achieved and also spacings between substrate and plasma source. Since noble gases are however very expensive, the use is unprofitable for many applications.

When using nitrogen or air, the plasma heats the operating gas up to some 100° C., which can lead to damage to the substrates to be treated.

DE 20 2004 008 285 U1 teaches a device for generating a plasma jet which uses an electrically controlled or a dielectric barrier discharge. However the problem remains here also of non-homogeneous treatment because of punctiform formation of the beam.

DE 94 056 11 U1 teaches the use of a barrier discharge such that the substrate is not located between the electrodes. In this system, the plasma is ignited between the electrodes and is blown out of the electrode gap onto the substrate. The low energy density of the discharge in particular poses problems here. This requires a small spacing between substrate and plasma source.

DE 43 32 866 A1 discloses a further proposal for use of dielectrically impeded discharges. Here a discharge is ignited between an electrode and a grating, the substrate being located on the side of the grating which is orientated away from the electrode. The substrate is modified by ultraviolet radiation and/or rapid electrons on the surface. Since the diffusion of the excited ions and molecules is very low, these do not contribute to surface modification or only directly at the grating. In particular, the energy-rich UV radiation is absorbed rapidly in air, which likewise greatly restricts the treatment effect. In addition, the electrons rapidly collide with neutral atoms and molecules and have only a very short lifespan and hence range. This significantly restricts the application of this arrangement.

WO 2004/051702 A2 likewise discloses a plasma generating device for the treatment of substrates with a plasma under atmospheric pressure.

This device has two electrodes which are disposed in a planar manner one above the other, a dielectric being located between the electrodes. The lower electrode has a large number of openings through which respectively a plasma flow can emerge in the direction of a substrate. There are possible here as the large number of openings also a type of perforated metal sheet. The holes however are throughout of a macroscopic dimension in this perforated metal sheet so that plasma beams with a large diameter are expelled.

It is therefore the object of the present invention to produce a plasma generating device and also a plasma generating method with which a plasma beam is generated, with which a substrate which is disposed outwith the plasma generating space can be treated, as homogeneous a gas flow as possible intending to be achieved, whilst lowering the gas consumption.

This object is achieved by the plasma generating device according to claim 1 and also the plasma generating method according to claim 18. Advantageous developments of the plasma generating device according to the invention and the plasma generating method according to the invention are provided in the respective dependent claims.

According to the invention, the object of the present invention is achieved in that a plasma generating device which has two electrodes is used, between which a dielectric is disposed as discharge barrier. This dielectric barrier prevents direct short circuiting of the electrodes. The electrical output and hence the temperature of the plasma are reduced in this way. In one of the electrodes, an opening is disposed as gas or plasma outlet, through which the plasma can be expelled in the direction of a substrate. According to the invention, a grating, net or fabric is now disposed over the cross-section of this opening. If a plurality of such openings is provided in the electrode, then one, several or even all of these openings can be provided with such a grating, net or fabric.

Such a grating, net or fabric homogenises the gas flow and leads to a sharp reduction in gas consumption. The cross-section of the opening is reduced by such a grating, net or fabric, however the flow rate increasing at the same time.

It was shown surprisingly that the plasma can also emerge through such a grating, net or fabric. Advantageously, the grating, net or fabric thereby has a porosity which characterises the permeability of the grating, net or fabric. This porosity can be varied and determined by type of weave, number of layers, screen size, -shape, -distribution, -orientation, phase content etc. Advantageously, the porosity of the grating, net or fabric is between 5% and 70%, advantageously between 30% and 55%.

The mesh width of the grating, net or fabric is advantageously between 0.0005 mm and 2 mm, advantageously between 0.01 mm and 0.5 mm. All mesh shapes are possible, in particular rectangular or square meshes. The net or fabric can be woven not only once but several times, be single or multilayer.

Gratings, nets or fabrics which are optically dense or light-impermeable can be used in particular. When using such nets, gratings or fabrics, it is particularly advantageous to set a pressure drop of the plasma across the grating, net or fabric of between 3 mbar and 50 bar.

The net can be disposed now on the side of the second electrode which is orientated towards the first electrode, can be disposed within the opening or even on the outside of the second electrode which is orientated towards the substrate.

Advantageously, the grating, net or fabric is conductive so that it can also supplement the function of the second electrode or take it over at the same time. The grating, net or fabric can also itself be part of the second electrode or represent the second electrode in the region of the openings. If the second electrode or the conductive net, grating or fabric has the potential of the substrate, then there is no potential difference between the plasma beam and the substrate. Then also conductive surfaces can be treated without forming hot discharges. In addition, the undesired rear-side treatment is avoided in all materials. The modifications on the surface of a substrate, which are achieved thus by the system, are however furthermore comparable with those of direct barrier discharge.

The shape of the openings can be variable. It is possible in particular that gaps, slots and/or holes are used as openings. In particular in the case of a gap, this can be orientated for example transversely relative to the feed direction of a substrate. The length of the gap then defines the width of the coated or treated region on the substrate. Due to suitable choice of gap length and electrode length, consequently adapted to any substrate, a complete or desired partial treatment of the substrate can be achieved.

A particular advantage relative to conventional barrier or “Corona” discharges resides in the fact that the described device operates without a counter-electrode and the generated plasma reaches the surface to be treated without potential. This makes it possible to treat both conductive, semiconductive and insulating substrates. An insulator in the sense of this invention is also a dielectric.

In a preferred embodiment, gap and gas flow are dimensioned such that flow rates of more than 2 m/s are achieved in the gap. Hence the range of the plasma is increased and it is possible to direct the plasma beam also onto further removed substrate surfaces.

The plasma beam of the device is outstandingly suitable for modification of surfaces. The system is not dependent upon the use of noble gases. Thus the most varied of gases such as e.g. air or nitrogen-, oxygen-, carbon dioxide-, hydrogen-, halogen-containing gases and gas mixtures are used.

Preferably but not necessarily, the gas contains only a little oxygen or layer-forming substances. Hence damage and contamination of the electrode arrangement can be avoided.

The plasma beam emerging from the device thereby impinges during treatment on the substrate and clings to the latter. As a result, a substantially wider treatment zone is produced than the dimension of the gap width or the cross-section of the jet. Consequently, the gap can be chosen to be small without a reduction in treatment zone resulting. In particular, the person skilled in the art will consider gap widths or diameters of 0.1 mm to 10 mm, in particular from 0.3 mm to 2 mm, in particular around 1 mm and also gap lengths between 5 cm and 200 cm, advantageously between 10 cm and 150 cm.

In order to obtain a wide treatment zone for the treatment of sheet goods or metal sheets, the electrode arrangement has a longitudinally extended configuration, e.g. approx. 15 cm to approx. 2 m, advantageously between 10 cm and 150 cm. As a result, sheet goods, such as e.g. packaging film, can be treated over the entire width in one operating step. The treatment duration results from the width of the plasma beam and the feed rate.

The spacing of the substrate can be chosen freely via the outlet length of the jet.

The linear jet relevant to the invention is also suitable for flat coating of surfaces. For this purpose, a coating gas or one enriched with a precursor (coating precursor) is fed in between two jets, which gas is activated in the discharge and is excited on the substrate for layer deposition. Since the gap or the net of the jet is subjected to a flow of non-coating gas, no parasitic contamination occurs there.

The treatment region can in addition be purged with an inert gas or be protected from penetration of environmental gases. As a result, oxygen-free treatments and coatings for example can be achieved and also undesired reactions avoided.

The excitation of the plasma between the electrodes can be effected by commercially available Corona generators. The discharge can be operated with typical voltages of a few hundred volts to a few 10 kV according to the breakthrough voltage of the gas. The frequency of the alternating voltage can likewise be chosen very freely in the range of a few Hz to a few MHz. The length of the jet is limited merely by the length of the electrodes. The gas supply can be homogenised over the entire region via gas distributors.

The thermal energy which is produced by the discharge is dissipated by the gas. If this does not suffice, the electrodes or the mounting thereof can be cooled. In order to achieve a specific throughflow, a pressure difference must be produced between the two sides of the net. This is typically between 1 mbar and 1 bar, particularly preferred between 1 mbar and 400 mbar. When selecting a suitable pressure difference, the person skilled in the art will take into account in particular the number and the size of the gaps, the desired gas throughflow and the desired range of the plasma.

In order to control the output, the treatment and the coating and also in order to homogenise the discharge between the electrodes or the net, the plasma can be pulsed by an intermittent voltage. The homogenisation can be promoted also by the additional introduction of UV radiation.

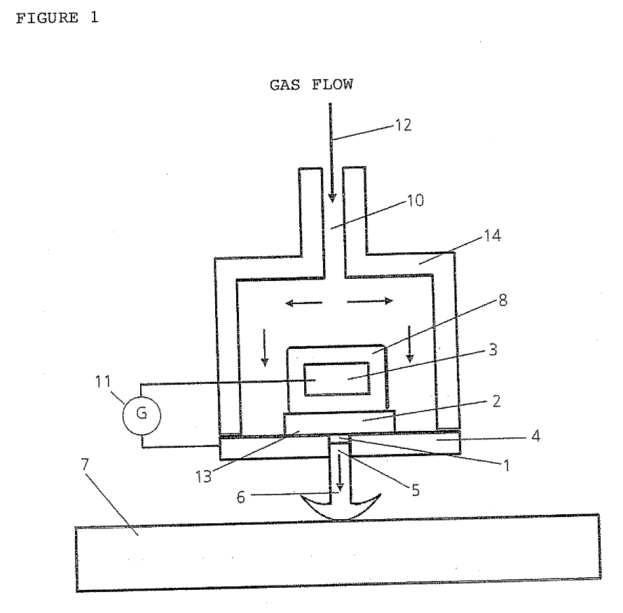

In a further embodiment of this arrangement, in addition to the parallel arrangement of the electrodes (FIG. 1), also further systems are possible. These can be for example symmetrical arrangements.

An example of a plasma generating device and method according to the invention is provided subsequently.

FIG. 1 shows a plasma generating device according to the invention.

The description of the FIGURE concerns the description of an embodiment, however individual aspects which are described in the context of the embodiment nevertheless having their own invention-relevant significance as individual aspects.

FIG. 1 shows the cross-section through a plasma generating device according to the invention. The latter has a first electrode 3 opposite which a second electrode 4 is situated and assigned, in the drawing, underneath. The first electrode 3 is surrounded by a dielectric 8 so that, by applying a high voltage from the high voltage source 11 to the electrodes 3 and 4, a barrier discharge occurs between the two electrodes 3 and 4 in the intermediate space 2 as discharge chamber. Furthermore, the first electrode 3 is surrounded by a housing 14 which has an inlet 10 for a gas flow 12 on the side of the electrode 3 which is orientated away from the electrode 4. This gas flows between the housing 149 and the electrode 3 into the discharge chamber 2 and there generates a plasma 13 under the high voltage barrier discharge.

The electrode 4 has an opening 5 which has a gap-like configuration. It extends, in FIG. 1, perpendicular to the drawing plane over the entire width of the substrate 7 shown in FIG. 1. A plasma jet 6 is expelled through this opening and impinges on the substrate 7. For example nitrogen is used here as operating gas and plasma gas.

Since an alternating voltage is applied to the two electrodes 3 and 4, a breakthrough field strength between the electrodes 3 and 4 can be achieved upon reaching a sufficient voltage so that the gas forms a plasma which is expelled from the gap 5 by the continuing inflowing gas flow 12 and burns outwith the device as a plasma jet 6. In the opening 5, a net 1 is disposed in addition, through which the plasma jet 6 penetrates. This net comprises stainless steel with a porosity of 45%. FIG. 1 shows a configuration of the plasma generating device in which the electrodes 3 and 4 are disposed parallel to each other in a planar manner. Symmetrical arrangements of the two electrodes are also possible.

In the following, two concrete embodiments are used which were implemented using the plasma generating device according to FIG. 1.

### EXAMPLE 1

A linear jet of 200 mm length with a gas gap of 1 mm width is operated with 50 slm nitrogen and a Corona generator with 150 W. The unit slm thereby denotes standard litre per minute, which means that as many gas particles flow out per minute as are contained in a volume of one litre at normal pressure of 1013.25 mbar and normal temperature of 293.15 K. The jet treats a BOPP film at a rate of 5 mm/s. Before treatment, the film has a surface energy of 30 mN/m. After treatment, the surface energy is 60 mN/m.

### EXAMPLE 2

A silicon wafer is treated as previously with the linear jet. Before treatment, the contact angle of a water drop on the wafer is 56°. After the treatment the contact angle is 15°.

1. Plasma generating device having
a first and a second electrode (3, 4) which are at a spacing from each other for generating a plasma (13) between the two electrodes (3, 4),
a dielectric (8) which is disposed between the two electrodes (3, 4),
a gas inlet (10) in the space between the two electrodes (3, 4) for supply of a plasma generating gas (12),
one of the two electrodes (3, 4) having at least one opening (5) as gas outlet from the space between the two electrodes (3, 4), through which the plasma (13), which can be generated between the two electrodes (3, 4), can be expelled parallel to the direction of the electrical field which can be produced by the two electrodes (3, 4) between the two electrodes (3, 4),
characterised in that
a grating, net and/or fabric (1) is disposed across the cross-section of the at least one opening (5).

2. Plasma generating device according to the preceding claim, characterised in that a grating, net or fabric (1) is disposed across the cross-section of several or all of the openings (5).

3. Plasma generating device according to claim 1, characterised in that the grating, net or fabric (1) is disposed on the second electrode (4) within or outwith the space between the two electrodes (3, 4) or within the opening (5).

4. Plasma generating device according to claim 1, characterised in that the grating, net or fabric (1) has a porosity between 5% and 70%, advantageously between 30% and 55% and/or a mesh width between 0.005 mm and 2 mm, advantageously between 0.01 mm and 0.5 mm.

5. Plasma generating device according to claim 1, characterised in that the grating, net or fabric (1) is gas- or plasma-permeable but optically dense or light-impermeable.

6. Plasma generating device according to claim 1, characterised in that the grating, net or fabric (1) is configured in such a manner that the pressure drop of the plasma (6) across the grating, net or fabric (1) is between 3 mbar and 50 bar, advantageously between 1 mbar and 1 bar, advantageously between 1 mbar and 400 mbar.

7. Plasma generating device according to claim 1, characterised in that the grating, net or fabric (1) is electrically conductive.

8. Plasma generating device according to the preceding claim, characterised in that the grating, net or fabric (1) is part of the second electrode (4).

9. Plasma generating device according to claim 1, characterised in that the grating, net or fabric (1) has or comprises stainless steel, steel, metal and/or porous sintered metal.

10. Plasma generating device according to claim 1, characterised in that the at least one, several or all of the openings (5) are configured as a gap, slot and/or hole.

11. Plasma generating device according to claim 1, characterised in that the at least one, several or all of the openings (5) have a cross-section which corresponds to a substrate (7) to be treated with the plasma beam (6), in particular the width thereof.

12. Plasma generating device according to claim 1, characterised in that the at least one, several or all of the openings (5) are configured such that the plasma (13) has a laminar flow during and/or after passage of the latter (13).

13. Plasma generating device according to claim 1, characterised in that the at least one, several or all of the openings (5) are configured as a nozzle.

14. Plasma generating devise according to claim 1, characterised in that the at least one, several or all of the of the openings (5) are configured as a gap with a width of between 0.1 and 10 mm, advantageously between 0.3 mm and 2 mm, advantageously between 0.3 mm and 1 mm and/or with a length of between 5 cm and 200 cm, advantageously between 10 cm and 150 cm.

15. Plasma generating device according to claim 1, characterised in that the two electrodes (3, 4) are disposed parallel to each other or symmetrically to each other.

16. Plasma generating device according to claim 1, characterised in that the first and/or second electrode (3, 4) has a length in the direction of the longitudinal direction of the openings (5) of between 5 cm and 200 cm, advantageously between 10 cm and 150 cm.

17. Plasma generating device according to claim 1, characterised in that the first and second electrode (3, 4) are connected to a high voltage source (11).

18. Plasma generating method, a plasma being generated between two spaced electrodes by means of barrier discharge and the plasma being expelled via an opening in one of the electrodes from the space between the two electrodes as a plasma beam parallel to the direction of the electrical field produced between the two electrodes, characterised in that
the plasma beam is guided through a grating, net and/or fabric disposed across the cross-section of the opening.

19. Plasma generating method, a plasma being generated between two spaced electrodes by means of barrier discharge and the plasma being expelled via an opening in one of the electrodes from the space between the two electrodes as a plasma beam parallel to the direction of the electrical field produced between the two electrodes,
characterised in that
the plasma beam is guided through a grating, net and/or fabric disposed across the cross-section of the opening,
characterised in that the plasma beam is generated by means of a plasma generating device according to claim 1.
